(19) United States
(12) Patent Application Publication
(10) Pub. No.: US 2014/0151642 A1
(43) Pub. Date: Jun. 5, 2014

(54) 3D RFICS WITH ULTRA-THIN SEMICONDUCTOR MATERIALS

(71) Applicant: INTERNATIONAL BUSINESS MACHINES CORPORATION, Armonk, NY (US)

(72) Inventors: SHU-JEN HAN, CORTLANDT MANOR, NY (US); ALBERTO VALDES GARCIA, HARTSDALE, NY (US)

(73) Assignee: INTERNATIONAL BUSINESS MACHINES CORPORATION, Armonk, NY (US)

(21) Appl. No.: 13/968,026

(22) Filed: Aug. 15, 2013

Related U.S. Application Data
(63) Continuation of application No. 13/705,845, filed on Dec. 5, 2012.

(51) Int. Cl. H01L 29/16

(52) U.S. Cl. CPC H01L 29/16; H01L 29/1606
USPC 257/29; 257/9

(57) ABSTRACT

Three-dimensional integrated circuits include an active layer having one or more active components formed with carbon-based channel material; a passive layer monolithically formed with the active layer, having one or more sub-layers and each sub-layer having one or more passive components, where the passive components have monolithically formed vertical interconnects to components on other layers; and a surface layer monolithically formed with the passive layer, including one or more surface components connected to one or more of the passive components through monolithically formed vias.

### RELATED APPLICATION INFORMATION

This application is a Continuation application of co-pending U.S. patent application Ser. No. 13/705,845 filed on Dec. 5, 2012, incorporated herein by reference in its entirety.

### BACKGROUND

1. Technical Field

The present invention relates to three-dimensional integrated circuits and, more particularly, to three-dimensional radio-frequency integrated circuits using graphene-based components.

2. Description of the Related Art

Typical radio modules include an integrated circuit (IC) or set of ICs that perform radio frequency (RF)/analog functions, an antenna or antenna array, and a carrier board that integrates the components. Usually, the components are separate modules of are partially integrated in a package. This increases the overall form factor, cost, and complexity of the overall assembly process.

Heterogeneous integration in one, two, or three dimensions is challenging if the verification and modeling tools are not integrated in the same platform. For example, modeling packaging separate from the ICs can result in frustrating mismatches and a lengthened design process.

To address this, some RFICs are integrated with antennas in a three-dimensional chip. The antennas are formed a side of the RFIC opposite from the board connections to allow for proper propagation of the RF signals. However, it is difficult to integrate antennas on-chip, and the resulting RFIC can only have terminals on one side. This problem has been addressed in the past by providing through-silicon vias (TSVs), conductive channels that penetrate layers of the three-dimensional chip that allow connections between components. TSVs are not a perfect solution, however, because they cause high loss and have significant parasitics in the radio frequency domain. From a design point of view, TSVs have a large footprint compared to other components. Furthermore, vertical integration of modules with TSVs involves complex processes that are not compatible with standard circuit manufacturing techniques. As such, TSVs usually are not employed for antenna or other radio-frequency interconnects, complicating the design of three-dimensional RFICs.

### SUMMARY

A method for forming a three-dimensional integrated circuit is shown that includes forming one or more passive components in a passive-layer dielectric; depositing additional dielectric material on the passive-layer dielectric; forming a gate structure in the additional dielectric material; forming a gate dielectric layer on the gate structure and the additional dielectric material; forming a thin channel material on the gate dielectric; forming source and drain regions in electrical contact with the thin channel material to form a transistor; and passivating the transistor and providing electrical access to the source and drain regions.

A method for forming a three-dimensional integrated circuit is shown that includes forming one or more surface components on a surface dielectric layer that is on a substrate; depositing a passive-layer dielectric material on the surface dielectric layer. forming one or more passive components in the passive-layer dielectric; depositing additional dielectric material on the passive-layer dielectric; forming a gate structure in the additional dielectric material; forming a gate dielectric layer on the gate structure and the additional dielectric material; forming a thin carbon-based channel material on the gate dielectric; forming source and drain regions in electrical contact with the thin channel material to form a transistor; passivating the transistor and providing electrical access to the source and drain regions; and etching the substrate to expose the one or more surface components.

A three-dimensional integrated circuit is shown that includes an active layer comprising one or more active components formed with carbon-based channel material; a passive layer monolithically formed with the active layer, comprising one or more sub-layers, each sub-layer having one or more passive components, wherein the passive components have monolithically formed vertical interconnects to components on other layers; and a surface layer monolithically formed with the passive layer, comprising one or more surface components connected to one or more of the passive components through monolithically formed vias.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a cross-sectional view of a three-dimensional integrated circuit in accordance with the present principles;

FIG. 2 is a cross-sectional view of a step of fabricating a three-dimensional integrated circuit in accordance with the present principles;

FIG. 3 is a cross-sectional view of a step of fabricating a three-dimensional integrated circuit in accordance with the present principles;

FIG. 4 is a cross-sectional view of a step of fabricating a three-dimensional integrated circuit in accordance with the present principles;

FIG. 5 is a cross-sectional view of a step of fabricating a three-dimensional integrated circuit in accordance with the present principles;

FIG. 6 is a cross-sectional view of a step of fabricating a three-dimensional integrated circuit in accordance with the present principles;

FIG. 7 is a cross-sectional view of a step of fabricating a three-dimensional integrated circuit in accordance with the present principles;

FIG. 8 is a cross-sectional view of a step of fabricating a three-dimensional integrated circuit in accordance with the present principles;

FIG. 9 is a cross-sectional view of a step of fabricating a three-dimensional integrated circuit in accordance with the present principles;

FIG. 10 is a cross-sectional view of a step of fabricating a three-dimensional integrated circuit in accordance with the present principles; and

FIG. 11 is a block/flow diagram of fabricating a three-dimensional integrated circuit in accordance with one illustrative embodiment.

### DETAILED DESCRIPTION OF PREFERRED EMBODIMENTS

Three-dimensional integrated circuits (ICs) provide substantial advantages over disparate chips arrayed horizontally on a board. First, three-dimensional integration substantially reduces the footprint of ICs by stacking components vertically. Vertical integration can furthermore increase performance by reducing the length of interconnections, thereby decreasing latency and power consumption.

The present principles provide three-dimensional chips and methods for making the same that are compatible with passive-first, active-last process flows that form passive components, such as capacitors and inductors, before active components, such as transistors. The present principles make use of thin channel materials such as graphene and/or carbon nanotube (CNT) to form active components, because graphene and CNTs can be readily applied to any flat surface, including pre-processed substrates. This allows active components to be formed on a surface with ball-grid array connections, with passive components being buried within the chip. There is therefore less need for through-silicon vias (TSVs), as connections between such components can be formed at the time of fabrication in a monolithic fashion. It should be understood that the present invention is not limited to carbon-based transistors and that other two dimensional materials, such as Molybdenum disulfide or other ultra-thin materials with nano-scale thickness, can be employed using the same principles.

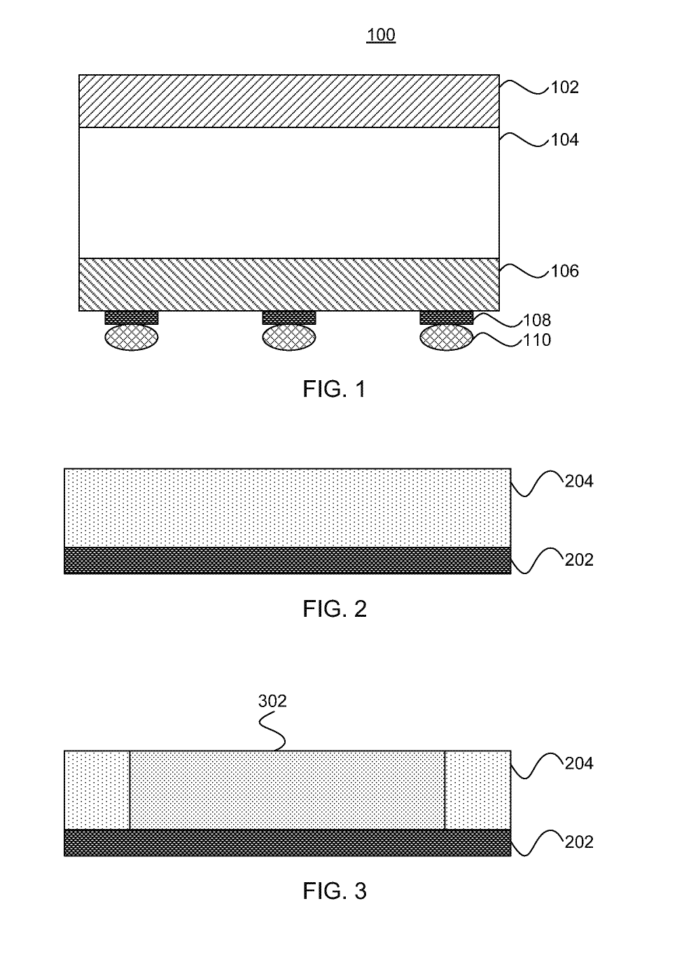

Referring now to the drawings in which like numerals represent the same or similar elements and initially to FIG. 1, a general diagram of a three-dimensional radio frequency integrated circuit (RFIC) 100 is shown. An antenna layer 102 is on top, allowing free broadcast of RF signals. The antenna layer 102 receives signals from passive components integrated in passive layer 104. The passive components interact with active components in active layer 106, forming the integrated circuit that drives the antennas in antenna layer 102. Pads 108 for a ball grid array (BGA) 110 allow bonding of the RFIC 100 to a board.

It should be noted that this design does not need TSVs to allow communication between layers because the chip is monolithically formed. Connections between antenna layer 102 and components in the passive and active layers 104 and 106 are formed as the layers themselves are fabricated. Whereas conventional three-dimensional chips use steps of physically grinding and reshaping an existing wafer to create TSVs, the present principles integrate existing processes by building the present chips up layer-by-layer. This monolithic integration also allows for complete modeling, simulation, and verification within the IC design flow.

Furthermore, although the present principles are described in relation to a radio frequency IC (RFIC), they may be extended to other uses as well. For example, the present embodiments may be formed with additional terminal pads instead of antenna layer 102. These surface components would allow heterogeneous vertical integration of the three-dimensional IC with other components, such as a complementary metal-oxide semiconductor chip. Additionally, another active component layer may be formed instead of antenna layer 102 using, e.g., ultra-thin devices as described herein. This layer may serve as, e.g., sensors/detectors. For example, if the surface active layer ends at a dielectric with no metal gate, a channel material can be used as a photodetector for optical communication. It should therefore be understood that the present principles can be extended to a wide variety of applications beyond the specific embodiments described herein.

It is to be understood that the present invention will be described in terms of a given illustrative architecture having a wafer; however, other architectures, structures, substrate materials and process features and steps may be varied within the scope of the present invention.

It will also be understood that when an element such as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for an integrated circuit chip of photovoltaic device may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Referring now to FIG. 2, a first step of three-dimensional IC fabrication is shown. A substrate 202 is formed from, e.g., a high-resistivity silicon layer. A dielectric layer 204 is deposited on the substrate 202. The dielectric layer 204 may be formed from, e.g., silicon dioxide or any other appropriate bulk dielectric. The specific materials to be used are given for the purpose of illustration and are not intended to be limiting. Those having ordinary skill in the art will recognize that there are many suitable alternatives and will be able to select materials best suited for their purpose. The silicon layer 202 forms the bottom of the chip during fabrication, but will be the top of the chip after completion, allowing for components formed in the dielectric layer 204 to be exposed.

Referring now to FIG. 3, a step of three-dimensional IC fabrication is shown. Surface components 302 are formed in the dielectric layer 204. The surface components 302 will be at the top of the chip after completion and may be exposed. One exemplary type of surface component 302 is an antenna array. To form such components, the dielectric layer 204 is etched using, e.g., reverse ion etching (RIE), allowing material for the components 302 to be deposited through such processes as low pressure chemical vapor deposition. In the case of an antenna, metal is deposited. After formation of components 302, the surface is planarized using, e.g., chemical-mechanical planarization (CMP).

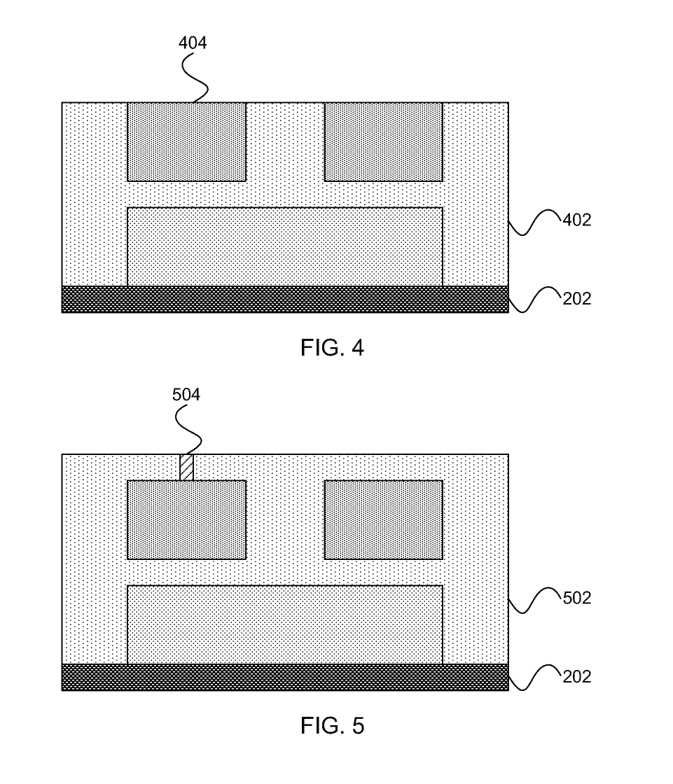

Referring now to FIG. 4, a step of three-dimensional IC fabrication is shown. Additional dielectric material is deposited, extending dielectric layer 402. The additional dielectric material should match the dielectric layer 204 described above, but it is contemplated that another dielectric material may be used if chemically compatible with dielectric layer 204 and advantageous for the formation of additional components. As above, the dielectric layer 402 is etched using, e.g., RIE, to allow space for passive components 404. The passive components 404 may include, e.g., capacitors, inductors, and interconnects between said components 404 and to the surface components 302. The surface is again planarized using, e.g., CMP.

Referring now to FIG. 5, a step of three-dimensional IC fabrication is shown. Additional dielectric material is deposited, extending dielectric layer 502. The dielectric layer 502 is etched using, e.g., RIE, to allow space for vias 504, which may be deposited using any appropriate process. The vias 504 connect passive components to one another and provide interconnects between layers. The surface is planarized using, e.g., CMP, to allow for deposition of the next layer. It should be recognized that the vias 504 are distinct from conventional TSVs, because TSVs go through a relatively thick silicon substrate, making them more lossy/inductive. TSVs thus are often hundreds of micrometers thick and have very low densities. The vias 504 disclosed herein pass through relatively short distances (e.g., hundreds of nanometers) in a dielectric layer 502 and may be formed in high densities, such that the vias 504 do not suffer the same shortcomings.

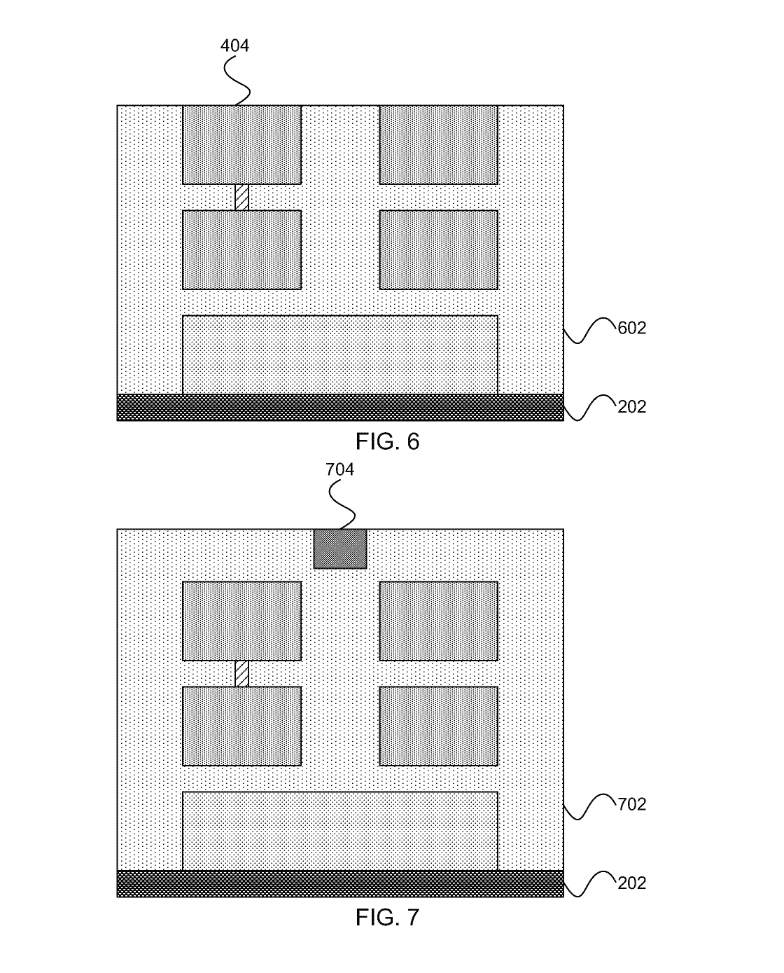

Referring now to FIG. 6, a step of three-dimensional IC fabrication is shown. Additional dielectric material is deposited, extending dielectric layer 602. Another layer of passive components 404 may then be added with interconnects to other components 404 as needed. This process may be repeated any number of times, producing an arbitrary number of layers of passive components 404. It should be recognized that the interconnects may be vertical, as shown above with vias 504, or may connect components 404 in a shared horizontal plane. The surface is planarized using, e.g., CMP.

Referring now to FIG. 7, a step of three-dimensional IC fabrication is shown. Additional dielectric material is deposited, extending dielectric layer 702. A gate 704 is added using an appropriate gate material such as, e.g., poly-silicon. Appropriate interconnects (not shown) may be formed between the gate 704 and the passive components to provide functional connectivity to the active components that are being formed.

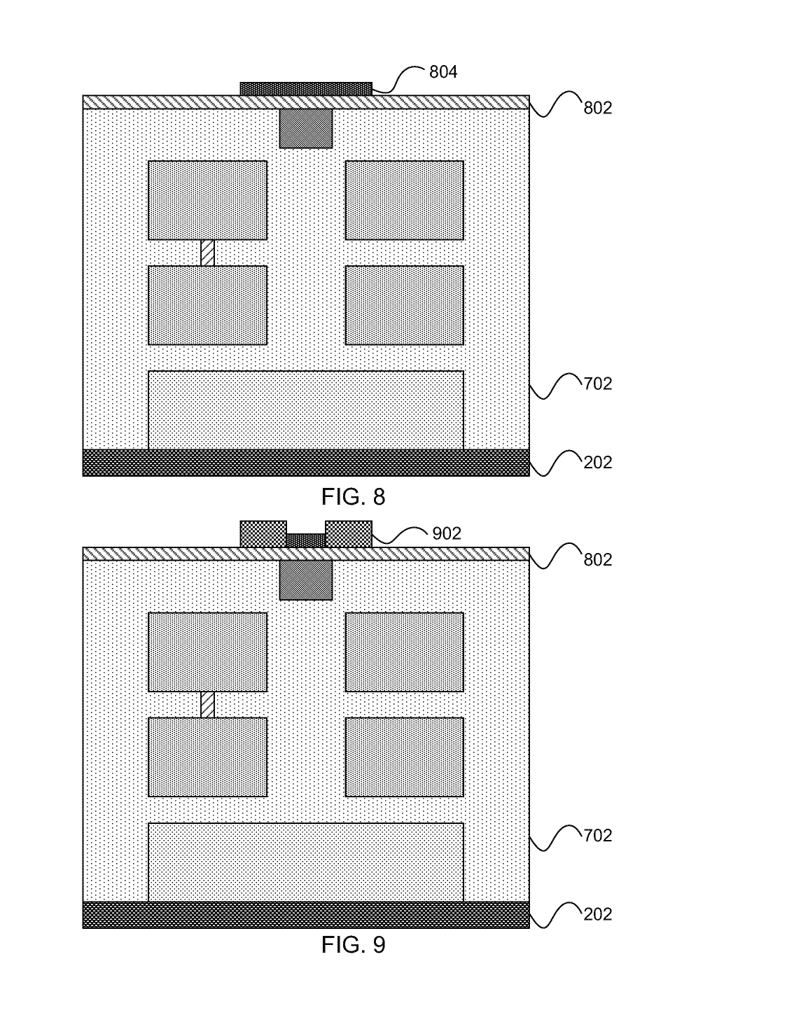

Referring now to FIG. 8, a step of three-dimensional IC fabrication is shown. A layer of gate dielectric material 802 is added and may be formed from any appropriate dielectric, such as silicon dioxide or a high-k dielectric. The gate dielectric 802 is formed over the entire surface, but may be etched in locations to allow contacts of devices to connect to components built inside the layers above. A thin layer of channel material 804 is deposited on the surface of the gate dielectric 802. Exemplary materials for the channel material 804 are graphene and CNTs. Graphene is a carbon monolayer with the thickness of a single atom. Graphene has high carrier mobility as well as low noise, which makes it particularly effective as a channel material. CNTs are molecular forms of carbon where a cylindrical lattice of carbon atoms can be extended indefinitely. Both graphene and CNTs are suitable for use in the present embodiments due to their small size, beneficial channel properties, and their ability to be transferred to any smooth surface. However, it should be recognized that any material that has a sufficiently small size and that may be easily applied to a surface may suffice as a channel material 804.

In one exemplary embodiment of forming a graphene channel, graphene may be initially formed on a separate substrate, e.g., copper. A handling layer of, e.g., poly(methyl methacrylate) (PMMA) is formed on the graphene and the copper substrate is dissolved. The PMMA layer is then used to manipulate the graphene into position in contact with the extended substrate gate dielectric 802. The PMMA layer is removed by any appropriate process, leaving the graphene channel material 804 exposed. This process can be performed using any suitably smooth surface, making the application of channel material possible at virtually any step in a fabrication process.

Referring now to FIG. 9, a step of three-dimensional IC fabrication is shown. Source and drain regions 902 are formed on the dielectric layer 802. The source and drain regions 902 may be formed from any appropriate material including, e.g., metal or silicide. The source and drain regions 902 connect to graphene/CNT channel 804, forming a transistor. Other active devices may be formed in a similar fashion and connected with passive devices 404. In the case of the transistor, the gate 704 may be triggered by, e.g., signals from the passive devices 404 or may have an external contact that is controlled by off-chip signals.

It should be recognized that the ICs described herein are not limited to the transistor construction described above. Conventional devices may also be formed on the same chip using, e.g., graphene first, followed by gate dielectric and gate metal deposition.

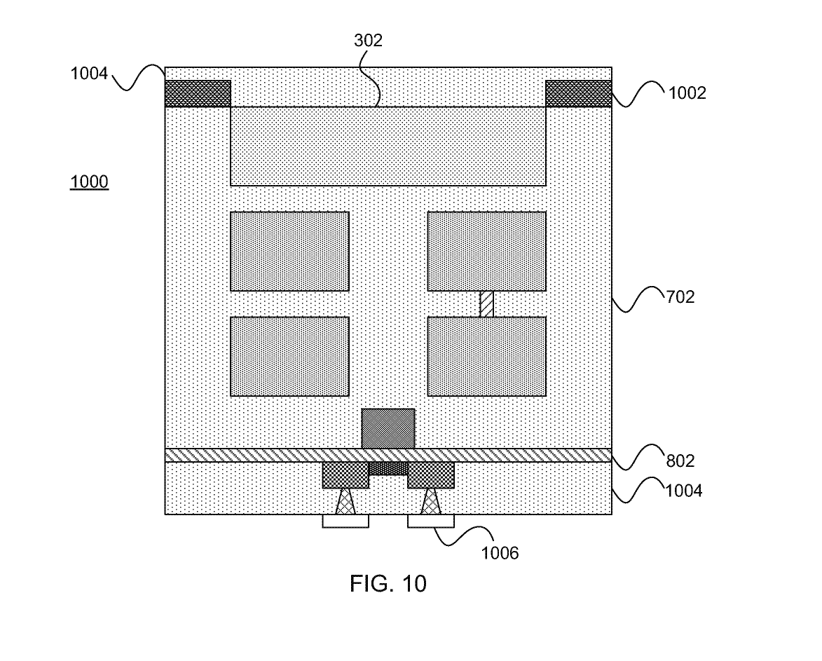

Referring now to FIG. 10, a finished three-dimensional IC 1000 is shown. The substrate 1002 is etched to expose the surface components 302 using, e.g., an appropriate wet etch such as ammonium hydroxide. In the case of an RFIC, these surface components 302 are antenna arrays, allowing the antennas to broadcast freely. A passivation layer 1004 is formed from, e.g., a dielectric, to insulate active components from one another and environmental hazards. A passivation layer 1004 may also be formed over the surface components 302, with the materials being selected to permit the passage of desired signals in the case of antennas. Contact pads 1006 are formed to contact the active components, providing electrical access from off-chip devices. It should be recognized that gate 704 may have an external connection, similar to that shown for the source and drain regions 902, though not shown in the present figures. It should also be noted that the orientation of the chip has been reversed. This passive-first process not only allows for integration with existing technologies, but also makes installation of the IC 1000 simple, without the need to, e.g., layer wafers.

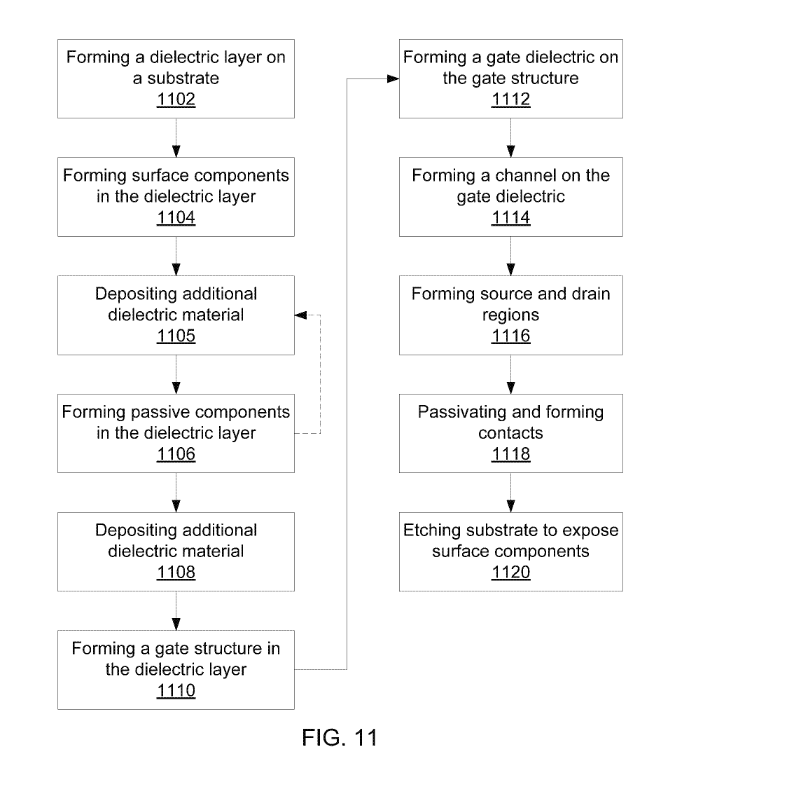

Referring now to FIG. 11, a method for forming a three-dimensional IC is shown. Block 1102 forms a dielectric layer 204 on a substrate 202. As described above, the substrate 202 may be formed from silicon while the dielectric layer 204 may be formed from silicon dioxide. Alternative materials may be used instead according to the judgment of the person having ordinary skill in the art. Block 1104 forms surface components 302 in the dielectric layer 202. This may be accomplished by etching channels into the dielectric layer 202 using, e.g., RIE, and filling said channels with a suitable component material. For example, the surface components 302 may be antennas for an antenna array.

Block 1105 deposits additional dielectric material and block 1106 forms passive components 404 in the extended dielectric layer 402. These steps may be repeated any number of times, with passive components 404 being interconnected vertically and horizontally. Although the FIGs shown herein show only one vertical interconnect, it should be recognized that only a cross-section is depicted, and that there may be arbitrary connections formed according to the present principles.

Block 1108 deposits additional dielectric material and block 1110 forms a gate structure 704 in the extended dielectric layer 702. The gate structure 704 may be formed from any appropriate gate material, such as poly-silicon. The poly-silicon may be deposited using any appropriate process including, e.g., low-pressure chemical vapor deposition. The gate structure 704 may be connected to passive components 404 using, e.g., integrally formed vias 504.

Block 1112 forms a gate dielectric 802 over the extended dielectric 702 and the gate structure 704. The gate dielectric 802 may be formed from any appropriate dielectric substance, such as silicon dioxide or a high-k dielectric. Block 1114 forms a channel 804 on the gate dielectric 802 from, e.g., graphene or CNTs, using any appropriate process. In one example, block 1114 forms the graphene/CNTs on a separate substrate and transfers them onto the surface of the gate dielectric 802.

Block 1116 forms source and drain regions 902. The source and drain regions may be formed by, e.g., building up silicon pads over the channel 804 and converting the pads to silicide, or by depositing metal directly onto the surface. Block 1118 then passivates the surface by filling in with, e.g., a dielectric layer 1004 such as silicon dioxide. Passivation shields the active components from corrosion and damage. Block 1118 also forms contacts through the passivation later 1004, providing an electrical interface to the active components. Block 1120 finishes the IC by etching the substrate 202 to expose surface components 302. In the case of an RFIC, this exposes an antenna for use.

Having described preferred embodiments of a system and method for graphene-based 3D RFICs (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims.

Having thus described aspects of the invention, with the details and particularity required by the patent laws, what is claimed and desired protected by Letters Patent is set forth in the appended claims:

1. A three-dimensional integrated circuit, comprising:
an active layer comprising one or more active components formed with carbon-based channel material;
a passive layer monolithically formed with the active layer, comprising one or more sub-layers, each sub-layer having one or more passive components, wherein the passive components have monolithically formed vertical interconnects to components on other layers; and
a surface layer monolithically formed with the passive layer, comprising one or more surface components connected to one or more of the passive components through monolithically formed vias.

2. The three-dimensional integrated circuit of claim 1, wherein the one or more surface components comprise an antenna.

3. The three-dimensional integrated circuit of claim 1, wherein the carbon-based channel material is formed from graphene.

4. The three-dimensional integrated circuit of claim 1, wherein the carbon-based channel material is formed from carbon nanotubes.

5. The three-dimensional integrated circuit of claim 1, wherein the circuit does not include through-silicon vias.

6. A three-dimensional radio frequency integrated circuit, comprising:
an active layer comprising one or more active components formed with carbon-based channel material;
a passive layer monolithically formed with the active layer, comprising one or more sub-layers, each sub-layer having one or more passive components, wherein the passive components have monolithically formed vertical interconnects to components on other layers and wherein the passive layer does not include through-silicon vias; and
a surface layer monolithically formed with the passive layer, comprising an antenna connected to one or more of the passive components through monolithically formed vias.
